(19) United States
(12) Patent Application Publication
(10) Pub. No.: US 2006/0204088 A1
(43) Pub. Date: Sep. 14, 2006

(54) METHOD AND APPARATUS OF IMAGE PROCESSING

(76) Inventors: Chun-Hsing Hsieh, Hsin-Chu City (TW); Hsien-Chun Chang, Chi-Lung City (TW); Jin-Sheng Gong, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/306,059

(22) Filed: Dec. 15, 2005

(30) Foreign Application Priority Data
Dec. 17, 2004 (TW) 093139436

(51) Int. Cl. G06K 9/00; G06K 9/40; G03F 3/08

(52) U.S. Cl. 382/167; 358/518; 382/274

(57) ABSTRACT

An image processing method for adjusting color data of an image is disclosed. The color space of the image is divided into a plurality of color grids and the method includes: providing a first table recorded a plurality of parameters corresponding to the plurality of color grids, respectively; receiving color data of the target pixel of the image; selecting a parameter from the first table according to the color data of the target pixel; and adjusting the color data of the target pixel according to the selected parameter.

### BACKGROUND OF THE INVENTION

1. Field of the Invention

The present invention relates to image processing techniques, and more particularly, to methods and apparatus for adjusting color data of images.

2. Description of the Prior Art

Image processing techniques continue to advance. As a result image display apparatuses are equipped with more and more functionalities. For example, some advanced digital television systems allow the user to adjust certain colors of the image to their liking (e.g., skin tone, grass color, or sky color), without affecting other image colors.

In general, the above color adjustment technique operates by adjusting pixels within a specific color range instead of merely adjusting pixels of a single color. Typically, many comparators are arranged in a conventional image display apparatus to subsequently perform comparison upon color data of each pixel, so as to determine whether the color of said pixel falls within the specific color range wherein colors are to be adjusted. However, if the goal is to achieve even finer color adjustment, more comparators are required. Consequently, cost and complexity of the hardware are increased significantly.

### SUMMARY OF THE INVENTION

It is therefore an objective of the claimed invention to provide image processing methods and apparatus to solve the above-mentioned problem.

An exemplary embodiment of an image processing method for adjusting color data of an image is disclosed. The color space of the image is divided into a plurality of color grids and the method comprises: providing a first table recorded with a plurality of parameters corresponding to the plurality of color grids, respectively; receiving color data of a target pixel of the image; selecting a parameter from the first table according to the color data of the target pixel; and adjusting the color data of the target pixel according to the selected parameter.

According to an exemplary embodiment, an image processing apparatus for adjusting color data of an image is disclosed. The color space of the image is divided into a plurality of color grids, the image processing apparatus comprises: a storage medium for storing a first table recorded with a plurality of parameters respectively corresponding to the plurality of color grids; a decision unit coupled to the storage medium for receiving color data of a target pixel of the image and for selecting a parameter from the first table according to the color data of the target pixel; and an computation unit coupled to the storage medium and the decision unit for adjusting the color data of the target pixel according to the selected parameter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of an image processing apparatus according to one embodiment of the present invention.

FIG. 2 is a schematic diagram of a color space of an image according to one embodiment of the present invention.

FIG. 3 is a block diagram of an image processor of FIG. 1 according to one embodiment of the present invention.

FIG. 4 is a schematic diagram of a first table stored in a storage medium of FIG. 3 according to one embodiment of the present invention.

### DETAILED DESCRIPTION

The image processing methods and apparatus according to embodiments of the present invention may be applied in various image display apparatuses and image output apparatuses such as: televisions, projectors, LCD displays, plasma displays, digital still cameras (DSC), scanners, printers, VCD/DVD players, etc. For the sake of illustration, the above listed devices or machines, or any other similar apparatuses are hereinafter collectively termed as an image display apparatus in the following embodiments to illustrate the image processing methods of the present invention.

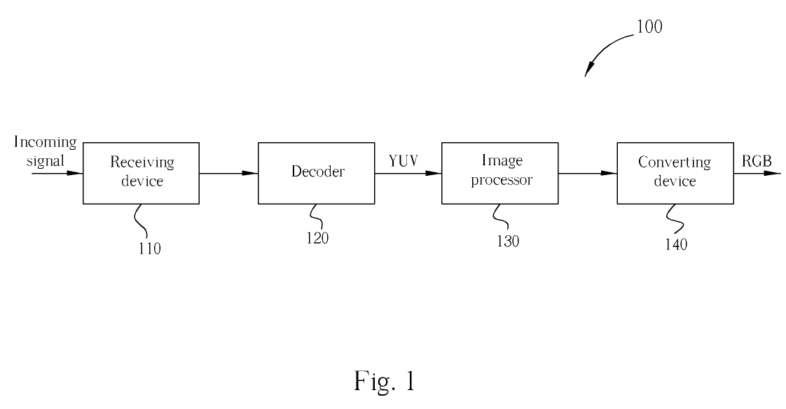

FIG. 1 shows a block diagram of an image processing apparatus 100 according to one embodiment of the present invention. The image processing apparatus 100 comprises a receiving device 110, a decoder 120, an image processor 130, and a converting device 140. The receiving device 110 is arranged for receiving an incoming signal. Typically, the incoming signal is a composite video signal. The decoder 120 is utilized for decoding and converting the incoming signal into a first image signal. The image processor 130 adjusts color data of a target image of the first image signal. The converting device 140 then converts the adjusted image data output from the image processor 130 into a second image signal. In this embodiment, the first image signal is typically a YUV signal and the second image signal is typically an RGB signal. The receiving device 110, the decoder 120, and the converting device 140 are well known in the art and further details are therefore omitted herein for brevity.

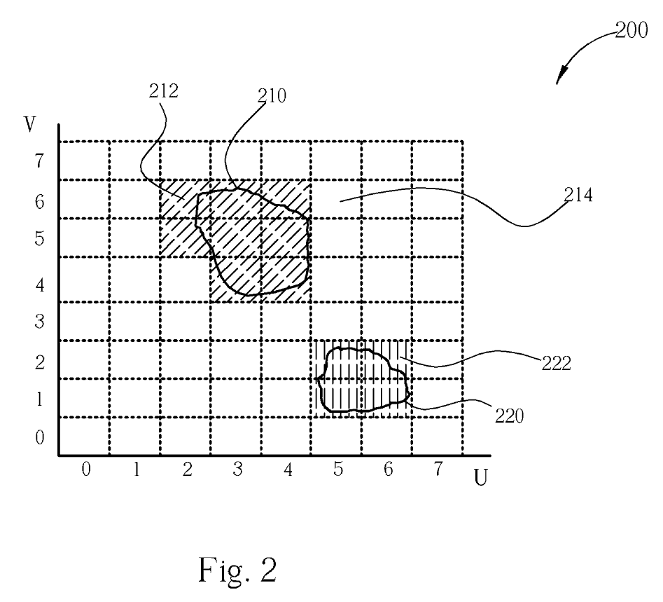

FIG. 2 illustrates a schematic diagram of a color space 200 of an image according to one embodiment of the present invention. In practice, the color space of images may be presented in two dimensions or three dimensions. In this embodiment, the color space 200 represents in two dimensions a chrominance space of the target image. Specifically, the color space 200 represents the UV space of the image because the image signal received by the image processor 130 is in YUV format. In practical implementations, the color space 200 may be predefined or divided into a plurality of color grids depending upon design requirement. For example, in the embodiment shown in FIG. 2, the color space 200 is divided into 8×8 (=64) color grids. In the following elaborations, each color grid of the color space 200 is defined as G(x,y), where (x,y) is the coordinate of the color grid in the UV space. For example, a color grid 212 is defined as G(2,6), a color grid 214 is defined as G(5,6), and a color grid 222 is defined as G(6,2). In FIG. 2, color regions 210 and 220 are two color regions to be adjusted by the image processor 130. As shown, the color region 210 corresponds to eight color grids of the color space, G(2,5), G(2,6), G(3,4), G(3,5), G(3,6), G(4,4), G(4,5), and G(4,6), while the color region 220 corresponds to four color grids, G(5,1), G(5,2), G(6,1), and G(6,2).

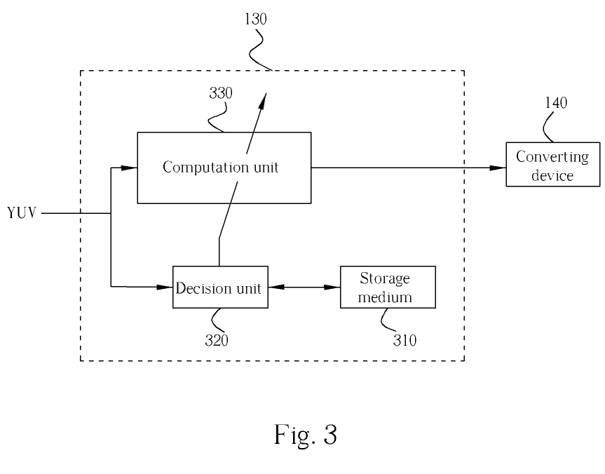

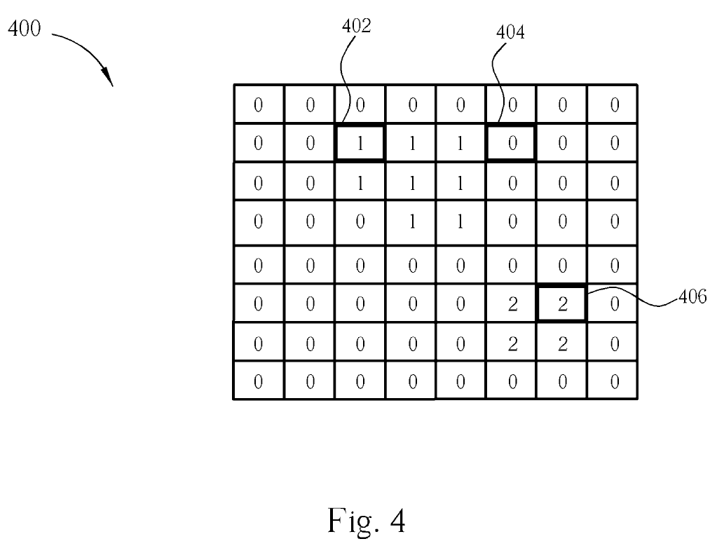

FIG. 3 shows a block diagram of the image processor 130 according to one embodiment of the present invention. The image processor 130 comprises a storage medium 310, a decision unit 320, and a computation unit 330. The storage medium 310 stores parameters of each of the color grids. Generally, the parameters are recorded in a table format. For example, an embodiment of a first table 400 stored in the storage medium 310 is shown in FIG. 4. The storage medium 310 records the parameters of each color grid of the color space 200 in a corresponding field of the first table 400. In this embodiment, the parameters of the color grid 212 of the color space 200 is recorded in a field 402 of the first table 400, the parameters of the color grid 214 is recorded in a field 404, and the parameters of the color grid 222 is recorded in a field 406. In practice, each field of the first table 400 may directly store a color adjustment setting of the corresponding color grid, such as a gain, a color offset, or a color adjust vector, etc. In this embodiment, the parameter recorded in each field of the first table 400 is an index, and the color adjustment settings of respective indexes are recorded in a second table (not shown). In this way, the required memory space of the storage medium 310 is greatly reduced. How the computation unit 330 adjusts the color data of the target pixel according to the color adjustment setting is well known in the art and not a major technical feature of the present invention; therefore, the operations of the computation unit 330 are omitted herein for brevity.

In this embodiment, the image signal received by the image processor 130 is in YUV format. In YUV format, the color data of each pixel of the target image includes a luminance value Y, a first chrominance value U, and a second chrominance value V. When the decision unit 320 of the image processor 130 receives the color data of a target pixel of the target image, the decision unit 320 references the first table 400 stored in the storage medium 310 according to the color data of the target pixel. Assume that each of the Y, U, V values of the pixel is represented in 8 bits. Since the color space 200 is divided into 8×8 (=64) color grids, the decision unit 320 can determine which color grid corresponds to the target pixel in two steps. First, both the three MSBs of the first chrominance value U and the three MSBs of the second chrominance value V of the target pixel are read out. Second, table look-up of the parameter recorded in a field of the first table 400 with respect to the determined color grid is then performed.

For example, assume that the first chrominance value U is 010XXXXX and the second chrominance value V is 110XXXXX (where X may be either 0 or 1). After reading the three MSBs of the value U, “010”, and the three MSBs of the value V, “110”, the decision unit 320 determines that the color of the target pixel is located within the color grid 212, i.e. G(2,6). Accordingly, the decision unit 320 then reads out a parameter “1” recorded in the field 402 corresponding to the color grid 212. Since the parameter “1” is an index, the decision unit 320 further selects a color adjustment setting from the second table according to the index “1.”

Similarly, assume that the first chrominance value U is 101XXXXX and the second chrominance value V is 110XXXXX. After reading the three MSBs of the value U and the three MSBs of the value V, the decision unit 320 determines that the color of the target pixel is located within the color grid 214, i.e. G(5,6). The decision unit 320 then accordingly reads out a parameter “0” recorded in the field 404 corresponding to the color grid 214. In this embodiment, the parameter “0” means that the color data of the target pixel does not require adjustment.

Following the same principle, if the first chrominance value U is 110XXXXX and the second chrominance value V is 010XXXXX, the decision unit 320 will select a index “2” recorded in the field 406 corresponding to the color grid 222, i.e. G(6,2). Next, the decision unit 320 will accordingly select a color adjustment setting corresponding to the index “2” from the second table.

In this embodiment, each combination of the value of the three MSBs of the first chrominance value U and the value of the three MSBs of the second chrominance value V of the target pixel directly maps to a corresponding address in the storage medium 310. Therefore, when the decision unit 320 processes the target pixel, it can determine where the target pixel is located within the color space 200 by reading the three MSBs of the first chrominance value U and the three MSBs of the second chrominance value V rather than reading all bits of the color data of the target pixel. Additionally, no comparator is required to compare the color data of the target pixel.

After the decision unit 320 selects the color adjustment setting of the target pixel as described above, the decision unit 320 controls the computation unit 330 to adjust the color data of the target pixel according to the selected color adjustment setting.

In a preferred embodiment, the computation unit 330 further determines a distance between the color position of the target pixel and a boundary of the corresponding color grid according to the remaining bits of the first chrominance value U and/or those of the second chrominance value V. The computation unit 330 then accordingly performs an interpolation operation to modify the color data of the target pixel to make different pixels within the same color gird present a color change utilizing a graduated (i.e., incremental) color change scheme.

Although in the forgoing embodiments the color space 200 is divided into 8×8 color grids, this is not intended to serve as limitation. In practice, depending upon the design choice, the color space 200 may be divided into M×N color grids, where M and N may be of the same value or different values. The bit number of the color data that the decision unit 320 reads out will be adjusted accordingly based on the different possible division sizes of the color space 200. For example, if the color space 200 is divided into 16×1 6 color grids, the decision unit 320 will then read out the four MSBs of the first chrominance value U and the four MSBs of the second chrominance value V.

In another embodiment, the above color space 200 may be extended from two-dimension UV space to three-dimension YUV space. In this embodiment, the decision unit 320 references the first table 400 according to a plurality of MSBs of the luminance value Y and the first and second chrominance values U, V of the target pixel.

In practice, the image processor 130 also can only store the parameters of at least one color grid corresponding to one or more color regions to be adjusted in the storage medium 310. In this embodiment, if the parameters corresponding to the color data of the target pixel exist in the storage medium 310, then the decision unit 320 selects one parameter from the storage medium 310 according to the color data of the target pixel and the computation unit 330 then adjusts the color data of the target pixel according to the selected parameter. If the parameters corresponding to the color data of the target pixel do not exist in the storage medium 310, then the decision unit 320 simply determines that the color data of the target pixel needs not to be adjusted. As a result, the required memory space of the storage medium 310 is further reduced.

In addition, the parameters recorded in each field of the first table 400 could be pre-configured or be programmed by users through a remote control or a command interface.

In the forgoing descriptions, the image processor 130 adjusts the color data of the image in the YUV domain. This is not meant to serve as a limitation of the present invention though. The disclosed method could also be applied to adjust color data of different format such as L/a/b, Y/I/Q, Y/Pb/Pr, Y/Cr/Cb, Y/R—Y/B—Y, or RGB format, etc.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image processing method for adjusting color data of an image, the color space of the image being divided into a plurality of color grids, the method comprising:
providing a first table recorded with a plurality of parameters corresponding to the plurality of color grids, respectively;
receiving color data of a target pixel of the image;
selecting a parameter from the first table according to the color data of the target pixel; and
adjusting the color data of the target pixel according to the selected parameter.

2. The method of claim 1, wherein the step of selecting the parameter comprises:
referencing the first table according to a portion of bits of the color data of the target pixel.

3. The method of claim 1, wherein the color data comprises first chrominance data and second chrominance data.

4. The method of claim 3, wherein the color data comprises luminance data.

5. The method of claim 1, wherein the parameter of one color grid is a corresponding color adjustment setting of the color grid.

6. The method of claim 1, wherein the parameter of one color grid is an index of the color grid, and color adjustment settings of the indexes are recorded in a second table.

7. The method of claim 6, wherein the step of adjusting the color data of the target pixel comprises:
selecting a color adjustment setting from the second table according to the index of the target pixel; and
adjusting the color data of the target pixel according to the selected color adjustment setting.

8. The method of claim 1, wherein the target pixel is Y/U/V, L/a/b, Y/I/Q, Y/P_{b}/Pᵣ, Y/Cᵣ/C_{b}, Y/R—Y/B—Y, or RGB format.

9. An image processing method for adjusting color data of an image, the color space of the image being divided into a plurality of color grids, the method comprising:
providing a first table recorded with parameters of at least one color grid corresponding to a color region to be adjusted;
receiving color data of a target pixel of the image;
referencing the first table according to the color data of the target pixel; and
if parameters corresponding to the color data of the target pixel being recorded in the first table, adjusting the color data of the target pixel according to the parameters.

10. The method of claim 9, wherein the step of referencing the first table comprises:
referencing the first table according to a portion of bits of the color data of the target pixel.

11. The method of claim 9, wherein the color data comprises first chrominance data and second chrominance data.

12. The method of claim 9, wherein the parameter of one color grid is a corresponding color adjustment setting of the color grid.

13. An image processing apparatus for adjusting color data of an image, the color space of the image being divided into a plurality of color grids, the image processing apparatus comprising:
a storage medium for storing a first table recorded with a plurality of parameters respectively corresponding to the plurality of color grids;
a decision unit coupled to the storage medium for receiving color data of a target pixel of the image and for selecting a parameter from the first table according to the color data of the target pixel; and
an computation unit coupled to the storage medium and the decision unit for adjusting the color data of the target pixel according to the selected parameter.

14. The image processing apparatus of claim 13, wherein the decision unit references the first table according to a portion of bits of the color data of the target pixel.

15. The image processing apparatus of claim 13, wherein the color data comprises first chrominance data and second chrominance data.

16. The image processing apparatus of claim 15, wherein the color data comprises luminance data.

17. The image processing apparatus of claim 13, wherein the parameter of one color grid is a corresponding color adjustment setting of the color grid.

18. The image processing apparatus of claim 13, wherein the parameter of one color grid is an index of the color grid, and the storage medium further stores a second table recorded with color adjustment settings corresponding to the indexes.

19. The image processing apparatus of claim 18, wherein the decision unit selects a color adjustment setting from the second table according to the index of the target pixel; and the computation unit adjusts the color data of the target pixel according to the selected color adjustment setting.

20. The image processing apparatus of claim 13, wherein the target pixel is Y/U/V, L/a/b, Y/I/Q, Y/P_{b}/Pᵣ, Y/Cᵣ/C_{b}, Y/R—Y/B—Y, or RGB format.
